(19) United States
(12) Patent Application Publication
(10) Pub. No.: US 2025/0273518 A1
(43) Pub. Date: Aug. 28, 2025

(54) METHOD FOR PRODUCING A MODULE BY ADHERING PARTS MADE OF DIFFERENT KINDS OF MATERIALS FOR A SEMICONDUCTOR ETCHING PROCESS

(71) Applicant: VM Inc., Icheon-si (KR)

(72) Inventors: Sang Woo LEE, Suwon-si (KR); Woo Hyung CHOI, Seongnam-si (KR); Tae Jin KWON, Anseong-si (KR)

(21) Appl. No.: 19/037,742

(22) Filed: Jan. 27, 2025

(30) Foreign Application Priority Data
Feb. 23, 2024 (KR) 10-2024-0026185

(51) Int. Cl. H01L 21/66; H01L 21/311; H01L 21/48

(52) U.S. Cl. CPC H01L 22/12; H01L 21/31116; H01L 21/4828; H01L 22/26

(57) ABSTRACT

A method for making a module of different kinds of parts comprises steps of: selecting two kinds of parts for performing a semi-conductor etching process; determining a property of an adhesive for adhering contacting surfaces of two selected parts; determining shapes of parts based on adhering surfaces; and adhering two kinds of parts the shapes of which are determined.

### BACKGROUND OF THE INVENTION

### Field of the Invention

The present invention relates to a method for producing a module by adhering parts made of different kinds of materials for a semiconductor etching process, in particular, the method for adhering different kinds of parts included in a semi-conductor etching equipment and made from different materials by an adhesive and forming a module capable of being assembled.

### Description of the Related Art

A semiconductor etching equipment applies a power of a high output specification for fitting a trend of the semiconductor market requiring a refinement of a pattern and a high aspect ratio, and various adjusting methods have been developed in response to such trend. Accordingly, as a material quality and a shape of a part have been diversified, the total number of parts has been increasing rapidly. There are lots of metal parts to which a power is applied and which play a role of a ground, due to the nature of the semiconductor equipment, and at the same time, the kinds and number of non-metal parts playing a role of an insulating material between the metal parts according to the relationship of the parts are increasing. A metal part and a non-metal part may be coupled each other by a coupling means such as a bolt or a rivet in course of being assembled. For example, in case of the upper electrode module of the prior art, the electrode and the insulator may be coupled by a coupling means such as the bolt or the like, and therefore, such coupling structure may have a disadvantage of process problems such as the corrosion of the coupled portion or a generation of a particle. Therefore, a method for coupling two different parts made of different materials needs to be developed for solving the problems of the prior art.

The present invention for solving the problems of the prior art has the following purposes.

### PURPOSE OF THE INVENTION

The object of the present invention is to provide with a method for producing a module by adhering parts made of different kinds of materials for a semiconductor etching process by adhering two different parts forming a process chamber for the semiconductor etching process and made from different kinds of materials with an adhesive for preventing a local generation of a plasma or a generation of a particle.

### SUMMARY OF THE INVENTION

In one embodiment of the present invention, a method for making a module of different kinds of parts comprises steps of: selecting two kinds of parts for performing a semiconductor etching process; determining a property of an adhesive for adhering contacting surfaces of two selected parts; determining shapes of parts based on adhering surfaces; and adhering two kinds of parts the shapes of which are determined.

In other embodiment of the present invention, the property of the adhesive comprises a tolerance to a plasma, a prevention of deposition of an intermediate product in course of etching process, a prevention of a particle generation, a prevention of change of a quality by a plasma or a prevention of corrosion by a plasma.

In another embodiment of the present invention, the adhering surfaces comprise at least a pair of bending surfaces.

In still another embodiment of the present invention, the adhesive is silicone-based or ceramic-based.

In still another embodiment of the present invention, a thermal expansion coefficient of the adhesive is smaller than that of at least one of two different kinds of parts.

In still another embodiment of the present invention, two different kinds of parts are a metal material part and a non-metal material part.

In still another embodiment of the present invention, two different kinds of parts are an inner electrode and a first insulator forming an upper electrode module, or an outer electrode and a second insulator.

In still another embodiment of the present invention, the inner electrode and the first insulator are a first module, and the outer electrode and the second insulator is a second module to be coupled to the first module.

### BRIEF DESCRIPTION OF THE DRAWINGS

FIG. 1 shows an embodiment of a method for producing a module by adhering parts made of different kinds of materials for a semiconductor etching process according to the present invention.

FIG. 2 shows an embodiment of a structure producing a module by adhering two different kinds of parts according to the present invention.

FIG. 3 shows an embodiment of a process chamber made by applying the method according to the present invention.

FIG. 4 shows an embodiment of another method for producing a module according to the present invention.

### DETAILED DESCRIPTION OF EXEMPLARY EMBODIMENTS

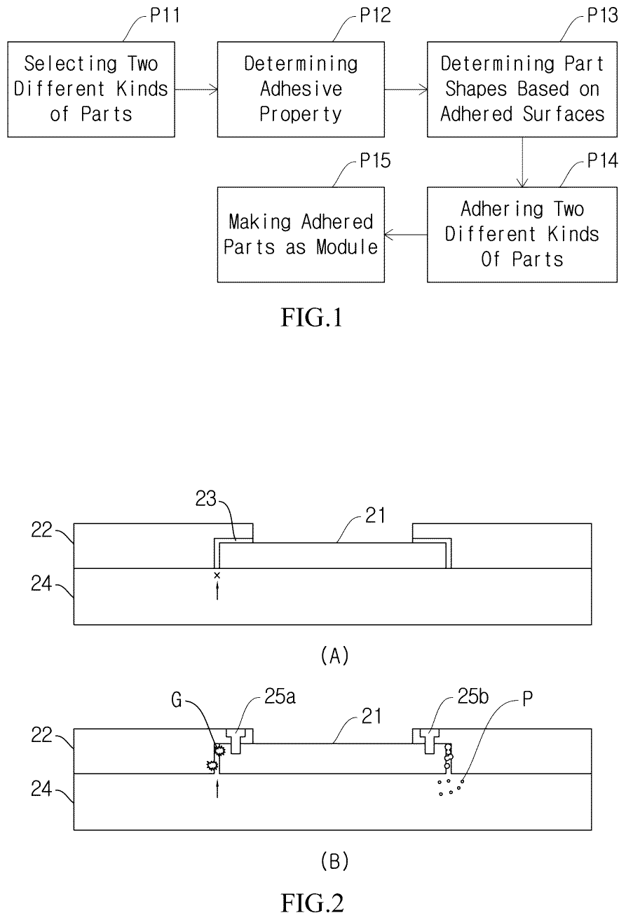

FIG. 1 shows an embodiment of a method for producing a module by adhering parts made of different kinds of materials for a semiconductor etching process according to the present invention.

Referring to FIG. 1, a method for making a module of different kinds of parts comprises selecting two kinds of parts for performing a semi-conductor etching process; determining a property of an adhesive for adhering contacting surfaces of two selected parts; determining shapes of parts based on adhering surfaces; and adhering two kinds of parts the shapes of which are determined. Preferably, at least a portion of the different kinds of parts may be exposed to the plasma, but not limited to.

The different kinds of parts may be two parts made from different materials and having different functions, and for example, the two different kinds of parts may become a first part made from a metal material and acting as an electrode and a second part made from a non-meatal material such as a ceramic and acting as an insulator. At least a portion of such first and second parts may be exposed to the plasma in course of an etching process, and there give rise to a process defect in course the etching process because of the exposure to the plasma. For example, a plasma may be generated at a coupled portion, or a particle may be generated. The first and the second part may be coupled each other, and at least one contacting surface may be formed. The at least one contacting surface may become various shapes, for example, the surface may become a circular contacting surface with a L-shape cross section, but not limited to.

If different kinds of the first part and the second part having at least one contacting surface and coupled each other are selected at step P11, the adhering property may be determined at step P12. The adhering property may be determined according to an installation or use purpose of the different kinds of parts, or according to a usage environment. Specifically, the property may comprise a resistance to a plasma generation or a resistance to a particle generation, and a volume having possibility of the plasma generation may be filled with the adhesive according to such adhesive property to prevent the plasma from being generated. The resistance to the plasma means that the adhesive has the resistance to the plasma and at the same time a quality of the adhesive does not change or the adhesive is not corroded by the plasma. The adhering property may comprise a nature that a phenomenon to create a process error such as a deposition of an intermediate product does not happen. And also, the adhering property may comprise a thermal expansion property, an elastic property, an insulating property, a tensile property or a stretch property. For example, the adhesive may have a smaller thermal expansion coefficient smaller than at least one part. And also, the adhesive may have the greater stretch property or the greater elastic property larger than at least one part.

The adhesive may become silicone-based or ceramic-based, and the adhesive may comprise SiO₂ or a silica component of 0.1 to 10 wt %, and the adhesive may comprise various kinds of organic components or inorganic components. The adhesive may have the tensile strength of 10 to kgf/cm²; an elongation rate of 40 to 200%; a dielectric breakdown strength of 5 to 40 KV/mm; an insulation coefficient of 2.4 to 8.0; an electrical resistance of 1.0×10¹⁴ to 1.0×10¹³Ω·cm²; an adhesive strength of 100 to 400 psi (kg·cm²); the thermal expansion coefficient of 0.5×10⁻⁶ to 1.0×10⁻⁴ cm/cm/° C.; a compressive strength of 50 to 300 kg/cm²; or a shear strength of 24 to 80 kg/cm², but not limited to.

The adhering property may be determined to have properties such as the resistance to the plasma generation, the resistance to the particle generation or the prevention of the deposition of the intermediate process product, but to maintain the solid adhering force during the etching process. If the property is determined at step P12, then a thickness of the adhering surface may be determined based on the adhering property and at the same time the shape of the first part and the shape of the second part may be determined at step P13. For example, the thickness of the adhering surface may become 10 to 2,000 μm, but not limited to. If a dimension of each part or the shape of each part is determined at step P13, the first part and the second part may be coupled each other by the adhesive at step P14. In this way, modularized parts may be made at step P15 by coupling the different kinds of parts made from different materials contacting at least one surface by the adhesive.

If a module is made by coupling two different kinds of parts, the module may be coupled to other part or other module as a modularized shape, for example, the module may be placed at a chamber for the etching process. For example, the module may become a portion of an upper electrode module placed within an etching process chamber. A portion of the adhesive applied to the adhering surface of two parts may be exposed to the plasma in course of the etching process, and the module made from two parts may become a portion of the electrode for generating the plasma. As discussed above, the adhesive may have the resistance to the plasma generation and the resistance to the particle generation, and thus the plasma may be prevented from being generated at the adhering surface and the particle may be prevented from being generated at the adhering surface exposed to the plasma in course of generating the plasma. An embodiment of an adhering structure of different kinds of parts will be discussed below.

FIG. 2 shows an embodiment of a structure producing a module by adhering two different kinds of parts according to the present invention.

Referring to FIG. 2, the first part 21 may be made from a metal material, and the second part 22 may be made from an insulating material such as a ceramic. The first part 21 may have a circular plate shape with one thickness, and the second part 22 may become a circular plate shape with another thickness. And a hole may be formed at the center portion of the second part 22. The second part 22 may be coupled to the first part 21 with the inner edge of the second part 22 contacting a circumferential area of the first part 21. In such coupling structure of the first and second parts 21, 22, a lower surface and a portion of contacting surface of the first and second parts 21, 22 may be exposed to the plasma area 24.

As shown in (B) of FIG. 2, when the parts 21, 22 made from different materials each other are coupled by coupling means 25a, 25b such as a bolt or a nut, various types tolerances may occur. Hence, such coupling structure may have a problem that a local plasma or a particle P may be generated. Specifically, the first part 21 and the second part 22 comprise horizontal contacting surfaces and vertical contacting surfaces, and a gap G may be created at the horizontal contacting surfaces or the vertical contacting surfaces. And the local plasma may be generated or the particle P may be generated by such gap G.

For preventing such gap G from being generated, as shown in (A) of FIG. 2, the contacting surface 23 of the first and second parts 21, 22 may be formed, and the contacting surface 23 may comprise a vertical contacting surface having a shape of an extending circular vertical strip and a horizontal contacting surface having a shape of an extending circular horizontal strip. The generation of the local plasma and the particle P may be prevented by forming such contacting surface 23. And also, the parts 22, 23 that are made from the different kinds of materials to be combined are coupled by the adhesive to become a module in such way, and thereby, an easiness of an assembling process of the total equipment and a maintenance of the assembled equipment may be improved.

In the semiconductor etching equipment, a flow of electricity and a flow of heat may become factors to influence a total capacity of the equipment, and hence, the adhesive forming the contacting surface 23 needs to have properties suitable for the characteristics regarding exposure to the plasma, various electromagnetic conditions generating in course of the etching process or a process condition such as a change of temperature. For example, the adhesive needs to have a suitable thermal expansion coefficient, an elongation characteristic or a heat conduction property, and the adhesive may comprise various additives for satisfying such characteristics. For example, the adhesive having a high heat conductivity or a large heat conduction characteristic needs to be used for adhering the upper electrode heater and a cooling means. On the contrary, a contacting surface 23 made from an insulating material may be formed at a portion except a volume the temperature of which increases by a heater, because it is inefficient and dangerous in safe view to emit heat to the outside. And also, it is advantageous for the contacting surface 23 to have a high insulating property, because the inner electrode and the outer electrode have to be insulated electrically.

The property of the adhesive may be selected properly according to the function of the first part 21 or the second part 22 or according to the condition of the etching process. For example, when the first part 21 becomes an electrode made from the metallic material and the second part 22 becomes an insulator made from non-metallic material, an insulation coefficient of the adhering surface 23 can be selected properly according to the properties of the materials. And also, the heat transfer coefficient of the adhering surface 23 may become equal to or smaller than that of the second part 22. The adhering property may be determined in various way, but not limited to.

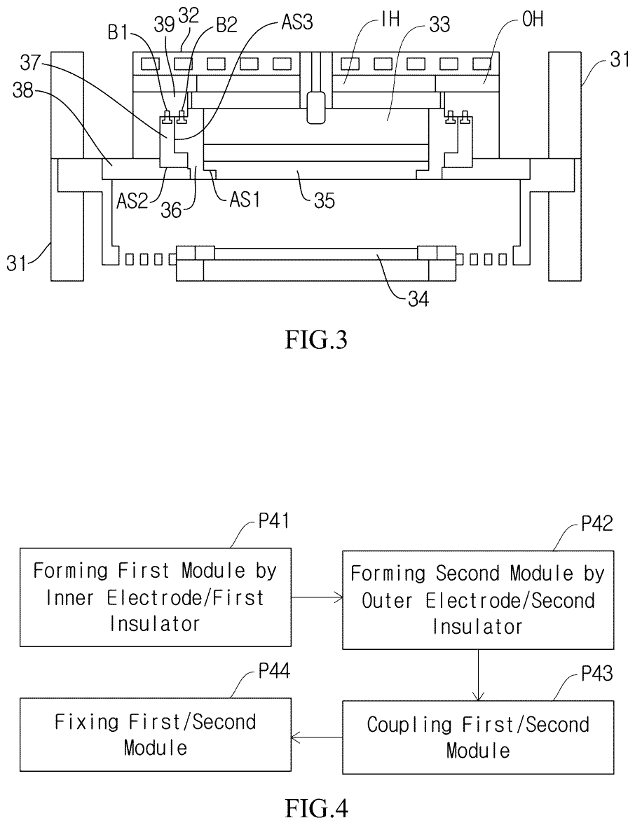

FIG. 3 shows an embodiment of a process chamber made by applying the method according to the present invention.

Referring to FIG. 3, the process chamber may comprise a perimeter wall 31, a lower electrode module 34; and the upper electrode module placed above the lower electrode module 34 and generating the plasma together with the lower electrode module 34.

The upper electrode module comprises an inner electrode 35 of a circular shape with a thickness; a first insulating part 36 made from a ceramic material and coupled to the perimeter surface of the inner electrode 35; a second insulating part 37 disposed at the outside of the first insulating part 36 and made from a non-metallic material such as a quartz; and an outer electrode 38 coupled to the second insulating part 37 and disposed at the outside of the inner electrode 35. An inner heater IH for controlling the inner electrode 35 and the outer electrode 38 and a cooling means 32 may be installed, and the inner electrode 35 may be fixed at a predetermined position by a gas distribution plate 33. The gas distribution plate 33 may function as a fixing block for fixing the inner electrode 35 placed at the lower position. And also, the first and second insulating parts 36, 37 and the outer electrode 38 may be fixed at a predetermined by a supporting block 39. An upper portion of the first and second insulating parts 36, 37 may be coupled to the supporting block 39 by coupling units B1, B2. The inner electrode 35 and the outer electrode 37 may become a silicone electrode, but the electrode material is not limited to that.

In the etching process chamber with such structure, a circular contacting surface with a L-shaped vertical cross section may be formed between the inner electrode 35 and the first insulating part 36 made from a ceramic material, and the contacting surface may be adhered by an adhesive to form a first adhering surface AS1. And also, a second adhering surface AS2 may be formed between the outer electrode 38 and the second insulating part 37 or the outer electrode 38 and the first insulating part 36. And also, a third adhering surface AS3 may be formed between the first insulating part 36 and the second insulating part 37. In this way, the contacting surface of the inner electrode 35 and the first insulating part 36 may become the first adhering surface AS1 to couple the inner electrode 35 and the first insulating part 36 in course of assembling the upper electrode module of an oxide film etching process chamber. Accordingly, it is impossible for a tap working to be performed to a ceramic material part due to a quality of a silicone material, but it is possible for coupling and fixing working to be performed by applying the adhesive depending on the ceramic material shape. The gap that is generated between the ceramic part and the silicone electrode may be removed to prevent the local plasma or the particle from being generated by forming the first adhering surface AS1. And also, an easiness of a part replacement can be enhanced through the part modularization.

The adhesive forming the first adhering surface AS1 may have a high thermal conductivity advantageously, and preferably the thermal conductivity of the first adhering surface AS1 may be larger than that of the first insulating part 36 and may be equal to that of the inner electrode 35. A stair-shaped step may be formed at the inner electrode 36 for regulating an adhering area, thus the inner electrode 36 may be fixed at the first insulating part 36 stably. The second insulating part 37 made from the quartz may be installed in order that the coupling means B2, for example the bolt for fixing the first insulating part 36 made from the ceramic material and wrapping around the inner electrode at the supporting block 39, is not exposed. And the outer electrode 38 made from the silicone material and contacting a bending portion of the second insulating part may be installed along the lower perimeter surface of the second insulating part 37. The adhesive may be applied to such contacting surface to form the second adhering surface AS2, and two parts 37, 38 that are not secured easily by the tap task with a high task difficulty may be fixed easily. The characteristic of the adhesive forming the second adhering surface AS2 may become equal to or identical to that of the adhesive forming the first adhering surface AS1. The third adhering surface AS3 may be selectively formed, and other fixing means may be used for fixing the first and second insulting part 36, 37, but not limited to.

FIG. 4 shows an embodiment of another method for producing a module according to the present invention.

Referring to FIG.4, a method for make a module installed at an etching process chamber comprises forming a first bonding module by adhering the inner electrode and the first insulator at least a portion of which contacts the inner electrode to form the contacting surface by an adhesive at step P14; forming a second bonding module by adhering the outer electrode disposed at the perimeter surface of the inner electrode and the second insulator at least a portion of which contacts the outer electrode to form a contacting surface at step P42; and combining or coupling the first bonding module and the second bonding module at step P43; and fixing the first and second module combined or coupled each other at a fixing block at step P44.

The inner electrode and the outer electrode may form the upper electrode module or a shower head of the etching process chamber. The inner electrode may have a circular plate, the first insulator may contact the inner electrode in a way to surround the outer circumference of the inner electrode and the inner electrode and the first insulator may be made from different materials each other. The contacting surface of the inner electrode and the first insulator may become L-shaped or stair-shaped, and the adhesive may be applied to the contacting surface to form the bonding module at step P41. The outer electrode may be disposed in a form of surrounding the outside of the inner electrode, and the second insulator may be disposed on the outer electrode to form a contacting surface with the outer electrode in a L-shape or a stair-shape. The adhesive may be applied to such contacting surface to form the adhering surface, and hence, the outer electrode and the second insulator may be bonded to form the second bonding module at step P42.

The first and the second bonding module may be bonded or coupled in a suitable way according to a structure of the etching chamber, or selectively the first and second bonding module may be maintained in a contacting state without coupling means at step P43. Then, the first and second module may be fixed at the fixing block disposed at the etching process chamber by a coupling means or other suitable means such as a bolt at step P44, but not limited to.

As discussed above, at least of a portion of the inner electrode, the outer electrode, the firs insulator or the second insulator may be exposed to the plasma in course of the etching process. And also, the adhesive may have a resistance to the plasma generation or to the particle generation, and may have a suitable heat transfer property. The adhesive may have an adhering characteristic suitable for the etching process condition, but not limited to.

What is claimed is:

1. A method for making a module of different kinds of parts, comprising steps of:
selecting two kinds of parts for performing a semi-conductor etching process;
determining a property of an adhesive for adhering contacting surfaces of two selected parts;
determining shapes of parts based on adhering surfaces; and
adhering two kinds of parts the shapes of which are determined.

2. The method according to claim 1, wherein the property of the adhesive comprises a tolerance to a plasma, a prevention of deposition of an intermediate product in course of etching process, a prevention of a particle generation, a prevention of change of a quality by a plasma or a prevention of corrosion by a plasma.

3. The method according to claim 1, wherein the adhering surfaces comprise at least a pair of bending surfaces.

4. The method according to claim 1, wherein the adhesive is silicone-based or ceramic-based.

5. The method according to claim 1, wherein a thermal expansion coefficient of the adhesive is smaller than that of at least one of two different kinds of parts.

6. The method according to claim 1, wherein two different kinds of parts are a metal material part and a non-metal material part.

7. The method according to claim 1, wherein two different kinds of parts are an inner electrode and a first insulator forming an upper electrode module, or an outer electrode and a second insulator.

8. The method according to claim 7, wherein the inner electrode and the first insulator are a first module, and the outer electrode and the second insulator is a second module to be coupled to the first module.
